(19) United States
(12) Patent Application Publication
(10) Pub. No.: US 2006/0049513 A1
(43) Pub. Date: Mar. 9, 2006

(54) Thin module system and method with thermal management

(75) Inventor: Paul Goodwin, (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/193,954

(22) Filed: Jul. 29, 2005

Related U.S. Application Data
(63) Continuation-in-part of application No. 11/007,551, filed on Dec. 8, 2004.
Application No. 11/007,551 is a continuation-in-part of application No. 10/934,027, filed on Sep. 3, 2004.

(51) Int. Cl. H01L 23/34

(52) U.S. Cl. 257/712; 257/720; 257/723

(57) ABSTRACT

A flex circuit populated with integrated circuits on one or both sides and in one or more fields along the flex circuitry is wrapped about an edge of a supporting substrate. In preferred embodiments, the substrate is thermally conductive material. One side of the flex circuitry has a connective facility implemented in a preferred embodiment with edge connector contacts such as those that would allow the resulting module to be inserted into an expansion socket. In a preferred embodiment, integrated circuits (preferably memory CSPs) and any accompanying circuitry or buffers are arranged on one or both sides of a flexible circuit. In some embodiments, one or more thermal sensors or other indicators are thermally coupled to the module substrate.

### RELATED APPLICATIONS

This application is a continuation-in-part of U.S. patent application Ser. No. 11/007,551, filed Dec. 8, 2004, which application is a continuation-in-part of U.S. patent application Ser. No. 10/934,027, filed Sep. 3, 2004. U.S. patent application Ser. Nos. 10/934,027 and 11/007,551 are hereby incorporated by reference herein.

### FIELD

The present invention relates to systems and methods for creating high density circuit modules.

### BACKGROUND

The well-known DIMM (Dual In-line Memory Module) board has been used for years, in various forms, to provide memory expansion. A typical DIMM includes a conventional PCB (printed circuit board) with memory devices and supporting digital logic devices mounted on both sides. The DIMM is typically mounted in the host computer system by inserting a contact-bearing edge of the DIMM into a card edge connector. Systems that employ DIMMs provide, however, very limited profile space for such devices and conventional DIMM-based solutions have typically provided only a moderate amount of memory expansion.

As bus speeds have increased, fewer devices per channel can be reliably addressed with a DIMM-based solution. For example, 288 ICs or devices per channel may be addressed using the SDRAM-100 bus protocol with an unbuffered DIMM. Using the DDR-200 bus protocol, approximately 144 devices may be address per channel. With the DDR2-400 bus protocol, only 72 devices per channel may be addressed. This constraint has led to the development of the fully-buffered DIMM (FB-DIMM) with buffered C/A and data in which 288 devices per channel may be addressed. With the FB-DIMM, not only has capacity increased, pin count has declined to approximately 69 signal pins from the approximately 240 pins previously required.

The FB-DIMM circuit solution is expected to offer practical motherboard memory capacities of up to about 192 gigabytes with six channels and eight DIMMs per channel and two ranks per DIMM using one gigabyte DRAMs. This solution should also be adaptable to next generation technologies and should exhibit significant downward compatibility.

In a traditional DIMM typology, two circuit board surfaces are available for placement of memory devices. Consequently, the capacity of a traditional DIMMs is area-limited. There are several known methods to improve the limited capacity of a DIMM or other circuit board. In one strategy, for example, small circuit boards (daughter cards) are connected to the DIMM to provide extra mounting space. The additional connection may cause, however, flawed signal integrity for the data signals passing from the DIMM to the daughter card and the additional thickness of the daughter card(s) increases the profile of the DIMM.

Multiple die packages (MDP) are also used to increase DIMM capacity while preserving profile conformity. This scheme increases the capacity of the memory devices on the DIMM by including multiple semiconductor die in a single device package. The additional heat generated by the multiple die typically requires, however, additional cooling capabilities to operate at maximum operating speed. Further, the MDP scheme may exhibit increased costs because of increased yield loss from packaging together multiple die that are not fully pre-tested.

Stacked packages are yet another strategy used to increase circuit board capacity. This scheme increases capacity by stacking packaged integrated circuits to create a high-density circuit module for mounting on the circuit board. In some techniques, flexible conductors are used to selectively interconnect packaged integrated circuits. Staktek Group L.P. has developed numerous systems for aggregating CSP (chipscale packaged) devices in space saving topologies. The increased component height of some stacking techniques may alter, however, system requirements such as, for example, required cooling airflow or the minimum spacing around a circuit board on its host system.

As DIMM capacities and memory densities increase, however, thermal issues become more important in DIMM design and applications. Because of the directional air flow from a system fan, the heat generated in a typical DIMM is not evenly distributed. Consequently, different parts of the DIMM exhibit different temperatures during typical operations. As is well known, circuit performance and timing can be affected by temperature. Consequently, some circuitry on-board the DIMM will have different timing characteristics than other circuitry located closer to or further from the cooling air flow. In short, there will be a thermally-induced timing skew between constituent devices. This may not affect performance at slower speeds where timing windows are larger but as bus and RAM speeds increase, the thermally-induced skew between devices on a DIMM becomes more significant reducing the timing window or eye.

Consequently, thermal and memory usage information can be useful. Thermal performance is difficult to measure, however, because of placement and construction of a typical DIMM board. Typically, a thermal sensor is placed on a DIMM board in a manner devised to measure the temperature of memory ICs on the DIMM board. Often, the design of the design of the DIMM board does not adequately couple heat from the ICs to the thermal sensor. Such lack of coupling causes inaccurate thermal readings.

Thermal energy management in modules is an issue of increasing importance. What is needed, therefore, are systems and methods that provide enhanced module expansion, convenient indicators for thermal, usage and other application related data and management of thermal loading with minimization of thermally-induced skew amongst module devices.

### SUMMARY

A flex circuit populated with integrated circuits on one or both sides and in one or more fields along the flex circuitry is wrapped about an edge of a supporting substrate. One side of the flex circuitry has a connective facility implemented in a preferred embodiment with edge connector contacts such as those that would allow the resulting module to be connected to an expansion socket. In a preferred embodiment, integrated circuits (preferably memory CSPs) and any accompanying circuitry or buffers are arranged on one or both sides of a flexible circuit. In some embodiments, one or more thermal sensors or other indicators are thermally coupled to the module substrate.

### BRIEF DESCRIPTION OF THE DRAWINGS

FIG. 1 is a cross-sectional depiction of a circuit module devised in accordance with an embodiment of the present invention.

FIG. 2 depicts a contact-bearing first side of a flex circuit devised in accordance with a preferred embodiment of the present invention.

FIG. 3 depicts the second side of the exemplar flex circuit of FIG. 2.

FIG. 4 is an enlarged view of the area marked ‘A’ in FIG. 1.

FIG. 5 depicts a cross-sectional view of a module devised in accordance with a preferred embodiment of the present invention.

FIG. 6 depicts a cross-sectional view of another module devised in accordance with an alternative preferred embodiment of the present invention showing the module disposed in an edge connector socket.

FIG. 7 is a depiction of front and back views of a prior art module.

FIG. 8 is a guide for understanding subsequent thermal data tables of this disclosure.

FIG. 9 depicts a close up cross-sectional view of a portion of a module devised in accordance with an alternative embodiment of the present invention.

FIG. 10 depicts a plan view of a module devised in accordance with an embodiment of the present invention.

FIG. 11 illustrates exemplar thermal flow vectors in an embodiment of the present invention.

FIG. 12 depicts a flex circuit populated with ICs and a sensor in accordance with an embodiment of the present invention.

FIG. 13 shows a block diagram for sensor signals according to one embodiment of the present invention.

### DETAILED DESCRIPTION OF PREFERRED EMBODIMENTS

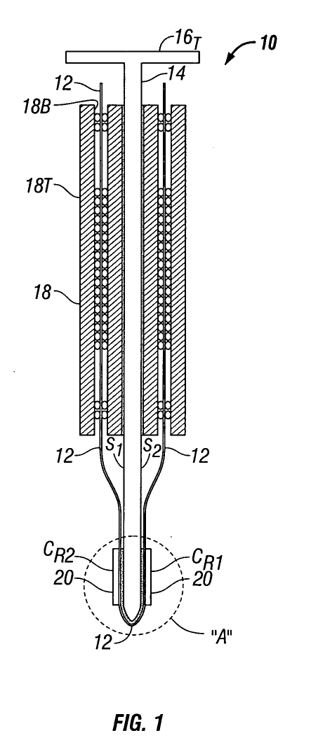

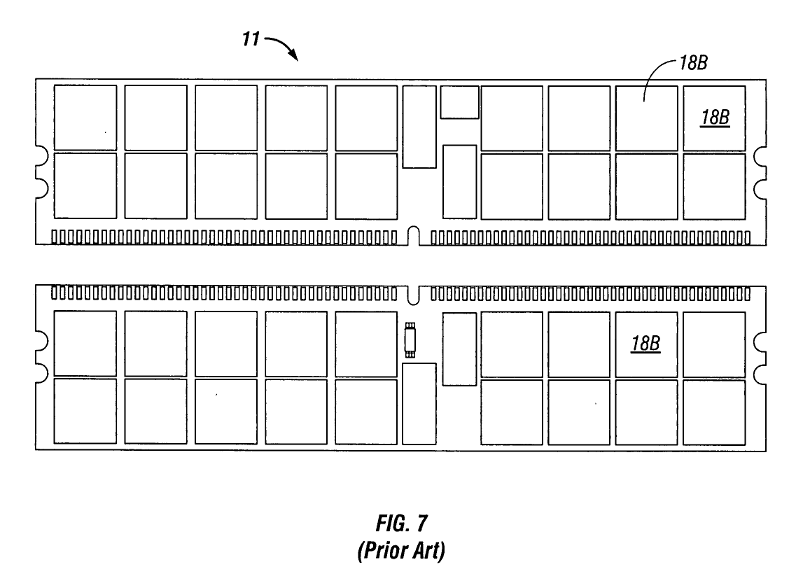

FIG. 1 depicts a preferred embodiment devised in accordance with the present invention. Module 10 of FIG. 1 exhibits ICs 18 disposed along each of two sides of flex circuitry 12 that is wrapped about substrate 14. Substrate 14 is preferably comprised of thermally-conductive material and may be, for example, comprised of a metallic material or thermally-conductive plastic or carbon material. In the depicted embodiment, substrate 14 exhibits extension 16T. Extension 16T may extend in one direction or, as shown, in two or more directions from the main body of substrate 14. The extension may diverge from the central axis of the substrate in any of a variety of orientations and need not be perpendicular in relation to the main body of the substrate. Those of skill will however recognize that most applications impose limitations on module profiles that will typically cause perpendicular arrangements for extensions to be preferred. Extension 16T provides thermal advantages to module 10 as will be shown. As will be shown in subsequent tables, under certain conditions, a model of a preferred exemplar module in accordance with the example of FIG. 1 demonstrates improved thermal performance including lower operating temperatures and reduced temperature variation from resident IC to resident IC when compared to a model of a more conventional circuit module such as that shown in later FIG. 7.

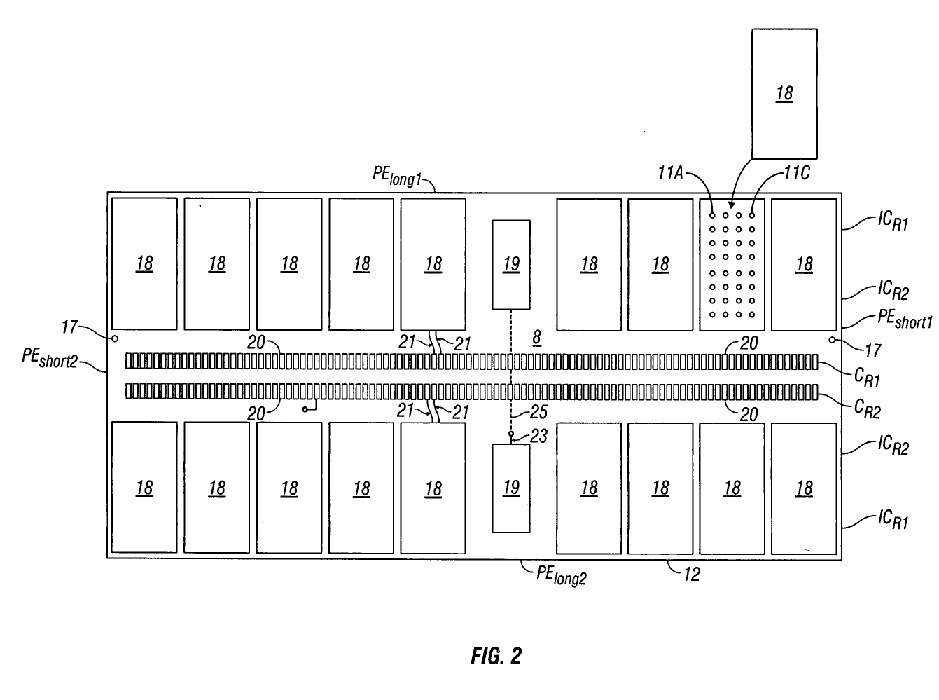

FIG. 2 depicts a first side 8 of flex circuit 12 (“flex”, “flex circuitry”, “flexible circuit”) used in constructing a module according to an embodiment of the present invention. Flex circuit 12 is preferably made from one or more conductive layers supported by one or more flexible substrate layers as further described with reference to later Figures. The construction of flex circuitry is known in the art. The entirety of the flex circuit 12 may be flexible or, as those of skill in the art will recognize, the flexible circuit structure 12 may be made flexible in certain areas to allow conformability to required shapes or bends, and rigid in other areas to provide rigid and planar mounting surfaces. Preferred flex circuit 12 has openings 17 for use in aligning flex circuit 12 to substrate 14 during assembly.

ICs 18 on flexible circuit 12 are, in this embodiment, chip-scale packaged memory devices. For purposes of this disclosure, the term chip-scale or “CSP” shall refer to integrated circuitry of any function with an array package providing connection to one or more die through contacts (often embodied as “bumps” or “balls” for example) distributed across a major surface of the package or die. CSP does not refer to leaded devices that provide connection to an integrated circuit within the package through leads emergent from at least one side of the periphery of the package such as, for example, a TSOP.

Embodiments of the present invention may be employed with leaded or CSP devices or other devices in both packaged and unpackaged forms but where the term CSP is used, the above definition for CSP should be adopted. Consequently, although CSP excludes leaded devices, references to CSP are to be broadly construed to include the large variety of array devices (and not to be limited to memory only) and whether die-sized or other size such as BGA and micro BGA as well as flip-chip. As those of skill will understand after appreciating this disclosure, some embodiments of the present invention may be devised to employ stacks of ICs rather than individual ICs. Multiple integrated circuit die may be included in a package depicted as a single IC 18.

While in this embodiment, memory ICs are used to provide a circuit board or module, various embodiments may include a variety of integrated circuits and other components and provide other functions besides or in addition to memory. Such variety may include microprocessors, FPGA's, RF transceiver circuitry, digital logic, as a list of non-limiting examples, or other circuits or systems which may benefit from a high-density circuit module capability. Circuit 19 depicted between ICs 18 may be a memory buffer or controller or sensor, for example. Circuit 19 may be the well known advanced memory buffer (AMB) for embodiments that comprise at least one instantiation of a fully-buffered DIMM, for example.

The depiction of FIG. 2 shows flex circuit 12 with contact arrays such as exemplar contact array 11A shown with exemplar IC 18 to be mounted at contact array 11A as depicted. The contact arrays 11A that correspond to an IC plurality may be considered a contact array set.

Side 8 of flex circuit 12 is shown populated with a first plurality of CSPS IC_{R1} and a second plurality of CSPs IC_{R2}. Those of skill will recognize that the identified pluralities of CSPs are, when disposed in the configurations depicted, typically described as “ranks”. Between the ranks IC_{R1} and IC_{R2}, side 8 of flex circuit 12 bears a connective facility implemented as a plurality of module contacts 20 allocated in this embodiment into two rows (C_{R1} and C_{R2}) of module contacts 20. In this embodiment, module contacts 20 are devised to be inserted into an edge connector socket as shown in a later Figure. Other embodiments may exhibit connective facilities that include sockets or connectors for direct wiring of the module into another circuit.

In those embodiments that employ a single flex circuit 12 folded about the edge 16A of substrate 14 as later depicted, side 8 depicted in FIG. 2 is presented at the outside of module 10. The opposing side 9 of flex circuit 12 is on the inside of module 10 in depicted configurations of module 10 and thus, side 9 is closer to the substrate 14 about which flex circuit 12 is disposed than is side 8. Other embodiments may have other numbers of ranks and combinations of plural CSPs connected to create embodiments in accord the present invention.

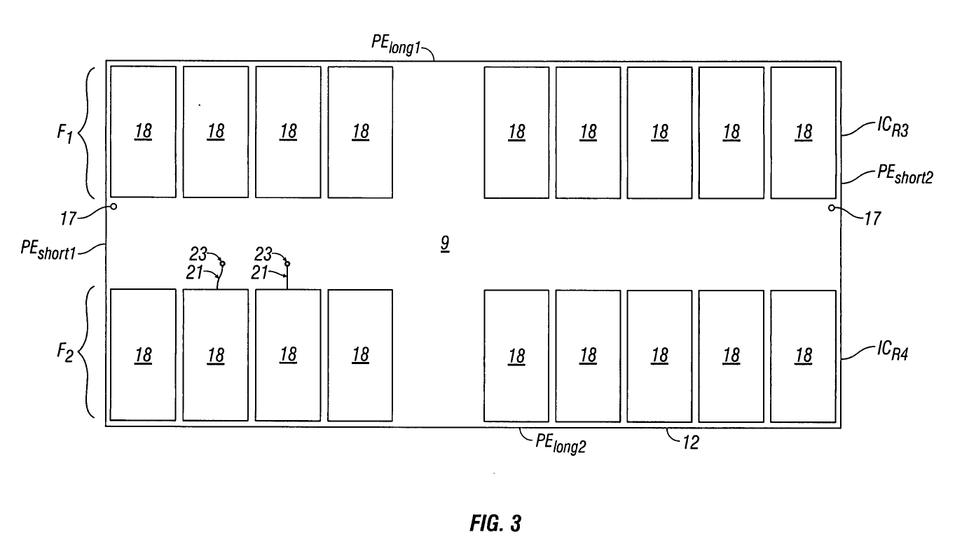

FIG. 3 shows side 9 of flex circuit 12 depicting the other side of the flex circuit shown in FIG. 2. Side 9 of flex circuit 12 is shown as being populated with multiple CSPs 18. Side 9 includes fields F1 and F2 each populated with, in the depicted preferred embodiment, at least one plurality of ICs identified in FIG. 3 as IC_{R3} and IC_{R4}. Thus, each side of flex circuit 12 has, in a preferred embodiment, at least two fields F1 and F2 each of which fields includes at least one plurality of CSPs. It will be recognized that fields F1 and F2 will be disposed on different sides of substrate 14 in a preferred module 10 when ICs 18 are identified according to the organizational identification depicted in FIGS. 2 and 3 but those of skill will recognize that the groupings of ICs 18 shown in FIGS. 2 and 3 are not dictated by the invention but are provided merely as an exemplar organizational strategy to assist in understanding the present invention.

Various discrete components such as termination resistors, bypass capacitors, and bias resistors, in addition to the circuits 19 shown on side 8 of flex circuit 12, may be mounted on either or both of sides 8 and 9 of flex 12. Such discrete components are not shown in these figures to simplify the depiction. Flex circuit 12 may also depicted with reference to its perimeter edges, two of which are typically long (PE_{long1} and PE_{long 2}) and two of which are typically shorter (PEₛₕₒᵣₜ₁ and PEₛₕₒᵣₜ₂). Other embodiments may employ flex circuits 12 that are not rectangular in shape and may be square in which case the perimeter edges would be of equal size or other convenient shape to adapt to manufacturing particulars. Other embodiments may also have fewer or greater numbers of ranks or pluralities of ICs in each field or on a side of a flex circuit.

FIG. 2 depicts an exemplar conductive trace 21 connecting row C_{R2} of module contacts 20 to ICs 18. Those of skill will understand that there are many such traces in a typical embodiment. Traces 21 may also connect to vias that may transit to other conductive layers of flex 12 in certain embodiments having more than one conductive layer. In a preferred embodiment, vias connect ICs 18 on side 9 of flex 12 to module contacts 20. An example via is shown as reference 23. Traces 21 may make other connections between the ICs on either side of flex 12 and may traverse the rows of module contacts 20 to interconnect ICs. Together the various traces and vias make interconnections needed to convey data and control signals amongst the various ICs and buffer circuits. Those of skill will understand that the present invention may be implemented with only a single row of module contacts 20 and may be implemented as a module bearing ICs on only one side of flex circuit 12. Trace 25 is shown to illustrate transition of a connection from one layer of flex circuit 12 to another at via 23.

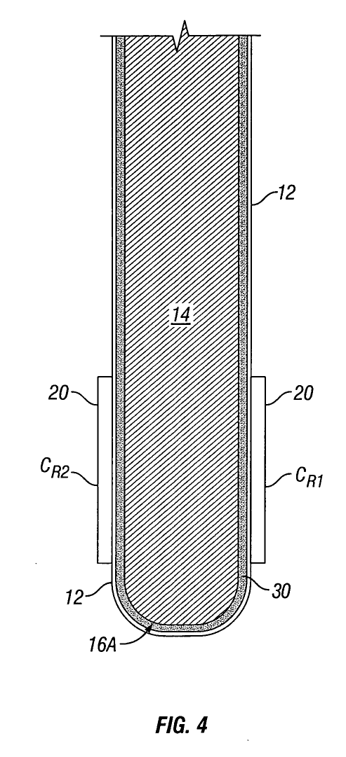

FIG. 4 is an enlarged view of the area marked ‘A’ in FIG. 1. Edge or end 16A of substrate 14 is shaped to function as a male side edge of an edge card connector. Edge 16A may take on other shapes devised to mate with various connectors or sockets. The form and function of various edge card connectors are well know in the art. In many preferred embodiments, flex 12 is wrapped around edge 16A of substrate 14 and may be laminated or adhesively connected to substrate 14 with adhesive 30. The depicted adhesive 30 and flex 12 may vary in thickness and are not drawn to scale to simplify the drawing. The depicted substrate 14 has a thickness such that when assembled with the flex 12 and adhesive 30, the thickness measured between module contacts 20 falls in the range specified for the mating connector. In some other embodiments, flex circuit 12 may be wrapped about perimeter edge 16B or both perimeter edges 16A and 16B of substrate 14. In other instances, multiple flex circuits may be employed or a single flex circuit may connect one or both sets of contacts 20 to the resident ICs.

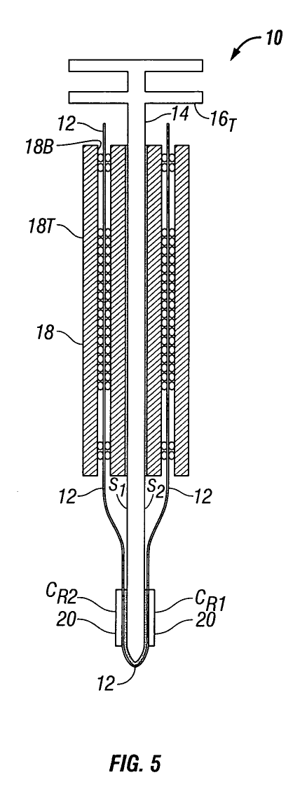

FIG. 5 depicts a cross-sectional view of a module 10 devised in accordance with another preferred embodiment of the present invention. The module 10 depicted in FIG. 5 differs from that shown in earlier embodiments in that rather than a single substrate extension 16T, two substrate extensions 16T are exhibited.

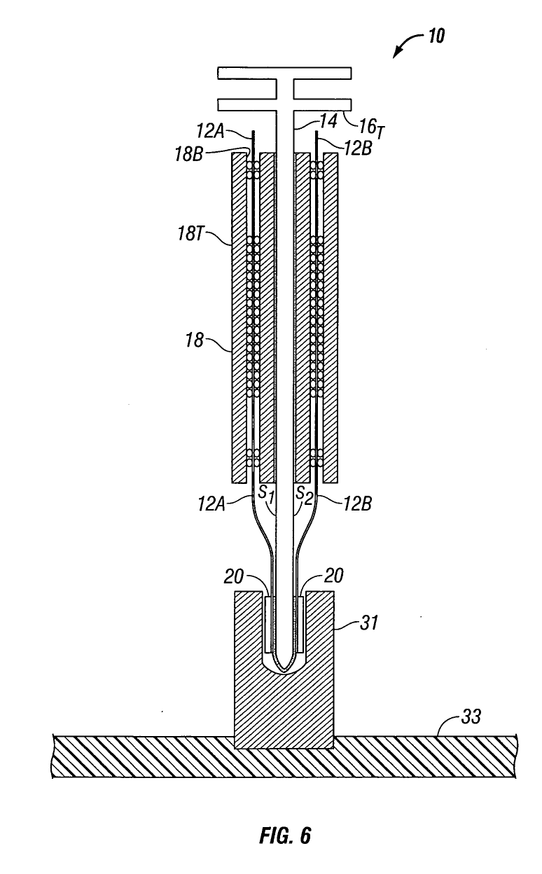

FIG. 6 depicts an alternate preferred embodiment of a module 10 in accordance with the invention that differs from the embodiment shown in FIG. 5 in that instead of the single flexibly circuitry 12 employed in the embodiment depicted in FIG. 5, the embodiment of FIG. 6 employs two flex circuits identified as 12A and 12B. Each of flex circuits 12A and 12B are populated with ICs 18 on one or both of their respective sides 8 and 9. Each of flex circuits 12A and 12B may employ adjunct circuits 19 such as, for example, buffers, sensors, or registers and PLL's for example on either of their respective sides. As those of skill will recognize, various embodiments may be devised to implement a variety of electrical or topologically-identified modules such as, for example, registered DIMMs, SO-DIMMs, video modules, FB-DIMMs with AMBs, and other modules.

U.S. patent application Ser. No. 11/007,551 filed Dec. 8, 2004 has been incorporated by reference and is owned by the assignee Staktek Group LP. That application discloses further details on FB-DIMM instantiations that can benefit from the present disclosure and should be referred to by those seeking further details and examples for such embodiments. Those of skill will recognize that the present invention can be adapted to express instantations of typical registered DIMM electronics to provide registered DIMMs with improved thermal performance. Similarly, video accelerator cards can be devised to adopt the present invention as can many other modules where thermal performance is an important issue in addition to those instances where convenience in manufacturing or minimization of profile are of high value. When a video card or other specialized module that includes a microprocessor is devised in accordance with the present invention, one or more of depicted circuits 19 can be considered a microprocessor.

With reference to the embodiment depicted in FIG. 6, each of flex circuits 12A and 12B has module contacts 20 positioned in a manner devised to fit in a circuit board card edge connector or socket 31 and connect to corresponding contacts in the connector (not shown). Edge connector or socket 31 is, as those of skill will recognize, typically a part of a computer 33. While module contacts 20 are shown protruding from the surface of flex circuit 12, other embodiments may have flush contacts or contacts below the surface level of flex 12. Substrate 14 supports module contacts 20 from behind flex circuit 12 in a manner devised to provide the mechanical form required for insertion into a socket. Substrate 14 in the depicted embodiment is preferably made of a metal such as aluminum or copper, as non-limiting examples, or alternatively, where thermal management is less of an issue, materials such as FR4 (flame retardant type 4) epoxy laminate, PTFE (poly-tetra-fluoro-ethylene) or plastic, for example, may be employed to devise substrate 14. In another embodiment, advantageous features from multiple technologies may be combined with use of FR4 having a layer of copper on both sides to provide a substrate 14 devised from familiar materials which may provide heat conduction or a ground plane.

FIG. 7 depicts a conventional DIMM module 11 populated with ICs 18B in a strategy sometimes called “planar” by those of skill in the art. The subsequent tables provide a comparison between a model of an exemplar module 11 such as depicted is FIG. 7 and a model of an exemplar module 10 in accordance with the present invention and devised in accordance with FIG. 1. As the tables demonstrate, there is substantially less thermal variation from IC to IC in module 10 (FIG. 1) than is found in a module such as is depicted in FIG. 7 under like conditions. The following data was generated by Staktek Group L.P., the present assignee of the invention.

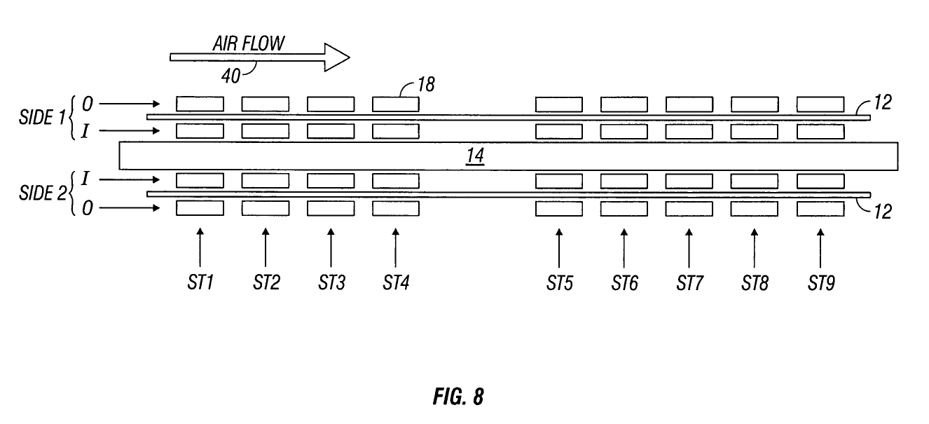

The following tables should be interpreted with reference to FIG. 8. FIG. 8 depicts a schematic of an embodiment of a module 10 in which the positions of the plural ICs of an exemplar module 10 are identified to assist in understanding the subsequent tables of this disclosure. For example, the IC 18 identified by specific reference in FIG. 8 is located at site 4 (reference “ST4”) of the outer side (reference “0”) of side 1 of the module. Airflow 40 is identified in FIG. 8 and will be quantified in subsequent tables. Positions or sites identified in FIG. 8 also identify corresponding sites in the module 11 evaluated in the table below identified with the suffix “B”. The tables are organized to provide ready comparison between the respective module 11 (exemplified by FIG. 7) and an exemplar module 10 (exemplified by FIG. 1) under the same conditions. Table 1A relates data derived from a model exemplar module 10 (exemplified by FIG. 1) while the table identified with a “B” suffix relates data derived from a model exemplar module 11 exemplified by the depiction of FIG. 7. As the data tables below relate, the models predict surprising and substantial differences in overall temperature and IC-to-IC temperature variation between a module 10 devised in accordance with FIG. 1 (with an extension on the substrate) with CSPs 18 and module 11 devised in accordance with FIG. 7 with ICs 18B under the commonly-known planar strategy. Those of skill will recognize that the predicted improvement in thermal conditions including reduced variation from IC-to-IC in the exemplified module 10 over that predicted for the exemplar module 11 should lead to reduced thermally-induced skew variation which would have salutary effects upon timing performance and timing eye tolerances for modules devised in accordance with FIG. 1 with a thermally-conductive substrate 14. Further exemplar modules such as that shown in FIG. 5 can be expected to demonstrate even further enhanced thermal performance. Those of skill will recognize that such improvements should also be expected with use of other substrates of thermally conductive materials such as, for example, copper or copper alloys. In addition to metallic materials, substrates 14 may also be devised from other thermally conductive materials such as, for example, carbon-based materials or thermally conductive plastics, for example.

Table 1A below relates thermal data derived from a modeled embodiment devised in accord with module 10 as described herein. The model exemplar module 10 was populated with plural Micron Technologies DDR2 (11X19) devices as ICs 18. In this instance, two exemplar modules 10 were modeled to be operating side to side with a 10 mm module pitch. Substrate 14 was comprised of aluminum and exhibited a topology exemplified by the depiction of FIG. 1. In the model, airflow 40 moved at 2 m/sec. at 35° C. while one rank of ICs 18 was operating at 0.38 watts per IC while the other rank was operating at 0.05 watts per IC.

TABLE 1A
Two Modules 10 (FIG. 1) Side to Side, 10 mm pitch, Aluminum Substrate
.38 W per device on one Rank, .05 W per device on other Rank
35 C. air at 2 m/s

| | | | | | | | | | | |
|---|---|---|---|---|---|---|---|---|---|---|
| Site 1 | Site 2 | Site 3 | Site 4 | Site 5 | Site 6 | Site 7 | Site 8 | Site 9 | Registers | PLL |

DIMM #1

| | | | | | | | | | | | |
|---|---|---|---|---|---|---|---|---|---|---|---|
| Side 1 | | | | | | | | | | | |
| Outer | 48.6 | 51.4 | 53.2 | 54.6 | 59.0 | 59.6 | 60.3 | 61.0 | 61.2 | 62.2 | |
| Inner | 54.0 | 55.8 | 57.5 | 58.9 | 62.0 | 63.0 | 63.8 | 64.2 | 64.2 | 64.9 | 68.1 |
| Side 2 | | | | | | | | | | | |
| Inner | 53.6 | 55.5 | 57.2 | 58.6 | 61.5 | 62.6 | 63.4 | 63.8 | 63.8 | 64.7 | |
| Outer | 55.0 | 58.8 | 60.8 | 62.4 | 63.6 | 65.9 | 67.1 | 67.7 | 68.0 | 62.6 | |

DIMM #2

| | | | | | | | | | | | |
|---|---|---|---|---|---|---|---|---|---|---|---|
| Side 1 | | | | | | | | | | | |
| Outer | 48.4 | 51.3 | 53.0 | 54.3 | 57.9 | 58.6 | 59.4 | 60.0 | 60.3 | 63.3 | |
| Inner | 54.1 | 55.9 | 57.6 | 59.1 | 62.2 | 63.3 | 64.1 | 64.6 | 64.6 | 64.6 | 68.0 |
| Side 2 | | | | | | | | | | | |
| Inner | 53.7 | 55.7 | 57.4 | 59.0 | 62.0 | 63.2 | 64.1 | 64.6 | 64.6 | 65.2 | |
| Outer | 55.5 | 58.9 | 61.0 | 62.8 | 65.4 | 67.5 | 68.8 | 69.6 | 69.9 | 63.4 | |

Maximum DRAM TEMP, C. 69.9
Minimum DRAM TEMP, C. 48.4
RANGE, C. 21.5

Table 1B below relates thermal data for an exemplar model module 11 devised in accordance with FIG. 7 operating under the same modeling conditions as those holding for Table 1A.

TABLE 1B
Two Modules 11 (Planar-DIMM configuration, FIG. 7), Side to Side, 10 mm pitch
.38 W per device on one Rank, .05 W per device on other Rank
35 C. air at 2 m/s

| | | | | | | | | | | |
|---|---|---|---|---|---|---|---|---|---|---|
| Site 1 | Site 2 | Site 3 | Site 4 | Site 5 | Site 6 | Site 7 | Site 8 | Site 9 | Registers | PLL |

DIMM #1

| | | | | | | | | | | | |
|---|---|---|---|---|---|---|---|---|---|---|---|
| Side 1 | | | | | | | | | | | |
| TOP | 50.6 | 53.9 | 56.3 | 58.5 | 62.7 | 63.9 | 64.9 | 65.5 | 65.1 | 63.3 | |
| BOTTOM | 58.2 | 62.1 | 64.7 | 66.6 | 70.4 | 72.6 | 72.9 | 73.1 | 73.1 | 64.3 | 72.0 |
| Side 2 | | | | | | | | | | | |
| TOP | 58.2 | 62.4 | 64.9 | 66.9 | 70.4 | 72.0 | 72.9 | 73.0 | 72.5 | 63.9 | |
| BOTTOM | 50.4 | 53.7 | 56.1 | 57.8 | 61.0 | 63.0 | 64.1 | 64.7 | 64.4 | 64.4 | |

DIMM #2

| | | | | | | | | | | | |
|---|---|---|---|---|---|---|---|---|---|---|---|
| Side 1 | | | | | | | | | | | |
| TOP | 50.5 | 53.8 | 56.2 | 58.3 | 62.1 | 63.2 | 64.1 | 64.5 | 63.9 | 63.0 | |
| BOTTOM | 58.0 | 62.0 | 64.6 | 66.4 | 69.4 | 71.6 | 72.8 | 73.0 | 72.8 | 63.8 | 71.6 |
| Side 2 | | | | | | | | | | | |
| TOP | 58.3 | 62.3 | 64.9 | 67.0 | 70.9 | 72.6 | 73.0 | 73.0 | 73.1 | 64.0 | |
| BOTTOM | 50.4 | 53.7 | 56.1 | 58.0 | 61.6 | 63.5 | 64.8 | 65.4 | 65.2 | 64.8 | |

Maximum DRAM TEMP, C. 73.1
Minimum DRAM TEMP, C. 50.4
RANGE, C. 22.7

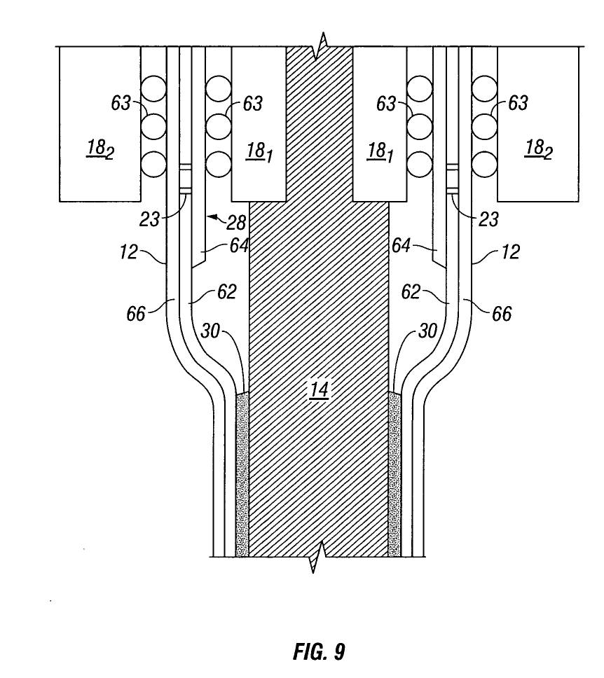

FIG. 9 is an enlarged view of a portion of one preferred embodiment showing lower IC 18₁ and upper IC 18₂ and substrate 14 having optional cutaway areas into which ICs 18 are disposed. In this embodiment, conductive layer 66 of flex circuit 12 contains conductive traces connecting module contacts 20 to BGA contacts 63 on ICs 18₁ and 18₂. The number of layers may be devised in a manner to achieve the bend radius required in those embodiments that bend flex circuit 12 around edge 16A. The number of layers in any particular portion of flex circuit 12 may also be devised to achieve the necessary connection density given a particular minimum trace width associated with the flex circuit technology used. Some flex circuits 12 may have three or four or more conductive layers. Such layers may be beneficial to route signals in a FB-DIMM which may have fewer DIMM input/output signals than a registered DIMM, but may have more interconnect traces required among devices on the DIMM, such as, for example, the C/A copy A and C/A copy B (command/address) signals produced by an FB-DIMM AMB.

In this embodiment, there are three layers of flex circuit 12 between the two depicted ICs 18₁ and 18₂. Conductive layers 64 and 66 express conductive traces that connect to the ICs and may further connect to other discrete components (not shown). Preferably, the conductive layers are metal such as, for example, copper or alloy 110. Vias such as exemplar vias 23 connect the two conductive layers 64 and 66 and thereby enable connection between conductive layer 64 and module contacts 20. In this embodiment having a three-layer portion of flex circuit 12, the two conductive layers 64 and 66 may be devised in a manner so that one of them has substantial area employed as a ground plane. The other layer may employ substantial area as a voltage reference plane. The use of plural conductive layers provides advantages and the creation of a distributed capacitance intended to reduce noise or bounce effects that can, particularly at higher frequencies, degrade signal integrity, as those of skill in the art will recognize. If more than two conductive layers are employed, additional conductive layers may be added with insulating layers separating conductive layers. Portions of flex circuit 12 may in some embodiments be rigid portions (rigid-flex). Construction of rigid-flex circuitry is known in the art.

The principles of the present invention may be employed where only one IC 18 is resident on a side of a flex circuit 12 or where multiple ranks or pluralities of ICS are resident on a side of flex circuit 12, or, where multiple ICs 18 are disposed one atop the other in stacks to give a single module 10 materially greater capacity.

The present invention may be employed to advantage in a variety of applications and environment such as, for example, in computers such as servers and notebook computers by being placed in motherboard expansion slots to provide enhanced memory capacity while utilizing fewer sockets. Two high rank embodiments or the single rank high embodiments may both be employed to such advantage as those of skill will recognize after appreciating this specification.

One advantageous methodology for efficiently assembling a circuit module 10 such as described and depicted herein is as follows. In a preferred method of assembling a preferred module assembly 10, flex circuit 12 is placed flat and both sides populated according to circuit board assembly techniques known in the art. Flex circuit 12 is then folded about end 16A of substrate 14. Flex 12 may be laminated or otherwise attached to substrate 14.

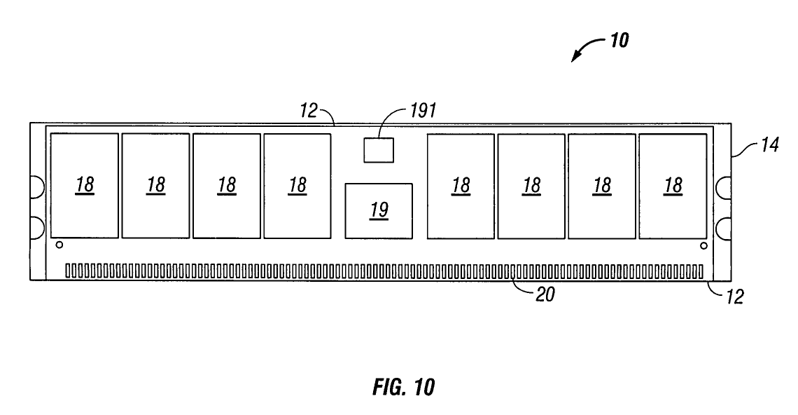

FIG. 10 depicts a module 10 according to another embodiment of the present invention. In this embodiment, module 10 is provided with a thermal sensor 191 mounted along inner side 9 of flex circuit 12. In the depiction of FIG. 10, even though showing side 8 of flex 12, the location of sensor 191 is depicted so that its location is understood in relation to the external view of module 10 provided in FIG. 10. Thermal sensor 191 is thermally coupled to substrate 14 in a manner devised to allow thermal measurements of substrate 14. Such arrangement is used to advantage in embodiments having a thermally conductive substrate 14, such as those made of copper, nickel, aluminum, carbon based materials or thermally-conductive plastic, for example. When ICs 18 along inner side 9 of flex circuit 12 are also thermally coupled to substrate 14, the temperature of substrate 14 will tend to match that of ICs 18.

In some embodiments, thermal sensor 191 may be integrated into a buffer or a register. For example, some FB-DIMM systems may employ one or more AMBs having an integrated thermal sensor. In such a module, one of the AMBs may be mounted along inner side 9 of flex circuit 12 and thermally coupled to substrate 14. The thermal reading taken from such an AMB may be used by the host system as a more accurate indication of module IC temperature than thermal readings taken from AMBs mounted along outer side 8.

In embodiments having more than one DIMM instantiation on a single module, a thermal sensor mounted along inner side 9 of flex circuit 12 may provide readings to be employed for one or more DIMM instantiations mounted along outer side 8. For example, one module may have four DIMM instantiations, two disposed adjacent to substrate 14 and two disposed along an outer side of flex circuitry away from substrate 14. Such a module may have two thermal sensors 191 thermally coupled substrate 14, one on either side. Each thermal sensor may provide a reading for the two DIMM instantiations at their respective sides of substrate 14. Alternatively, one thermal sensor may provide readings for all four DIMM instantiations.

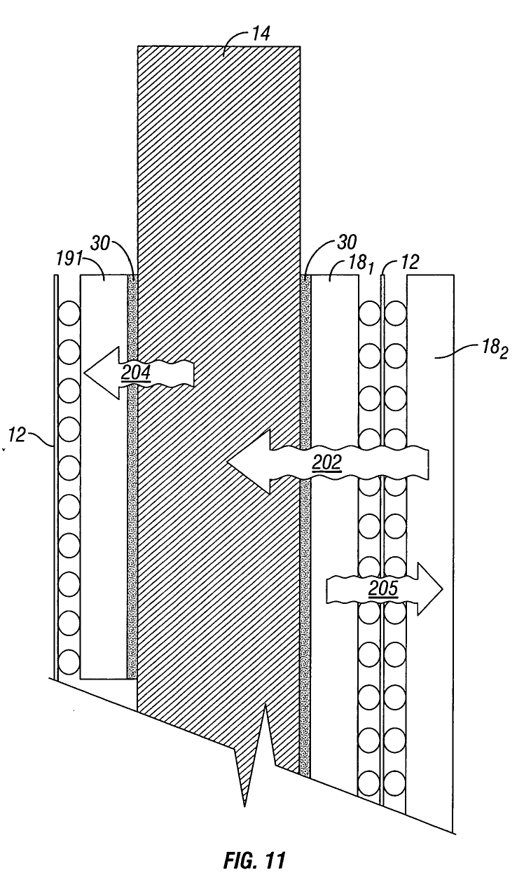

FIG. 11 depicts a cross-section view of another embodiment of the present invention. Thermal sensor 191 and one of the depicted ICs 18 are thermally coupled to substrate 14 with thermally conductive adhesive 30. Typically, other ICs 18 will be mounted to flex circuit 12 beside thermal sensor 191. In this embodiment, IC 18 and thermal sensor 191 have a similar thickness or height above the depicted flex circuitry 12. Other embodiments may be made with a thermal sensor having a height greater or less than ICs 18. Such a height difference may be adjusted by thermally conductive spacer such as, for example, a piece of copper or other metal. The height difference may also be adjusted by a fill of thermally conductive adhesive, the fill devised to dispose both ICs 18 and thermal sensor 191 in thermal connection to substrate 14. Arrow 202 in FIG. 11 shows flow of heat out of the depicted ICs 18 and into substrate 14. Arrow 204 shows flow of heat from substrate 14 to thermal sensor 191. Arrow 205 depicts a flow of thermal energy from an IC 181 to an IC 182. The disposition of ICs 181 and 182 opposite each other and separated by the flex circuitry 12 tends to encourage the flow of thermal energy from the one of the pair composed of IC 181 and IC 182 that is in the ON state to the one of the pair that is in the quiescent or state which shall mean either quiescent or OFF.

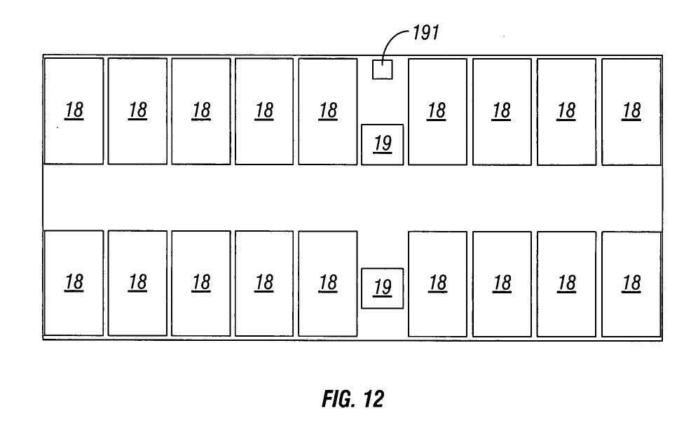

FIG. 12 is an elevation view of inner side 9 of a flex circuit 12 according to another embodiment of the present invention. Thermal sensor 191 is mounted along inner side flex circuit 12, and then flex circuit 12 is wrapped about the edge of substrate 14. While in this embodiment only one flex circuit is used, in other embodiments, such as that depicted in FIG. 6, two or more flex circuits may be combined with substrate 14 to form a module. In such embodiments, one or more thermal sensors 191 may be mounted to each flex circuit, or one thermal sensor may adequately measure thermal status for circuitry along both sides of substrate 14 by being thermally coupled to substrate 14.

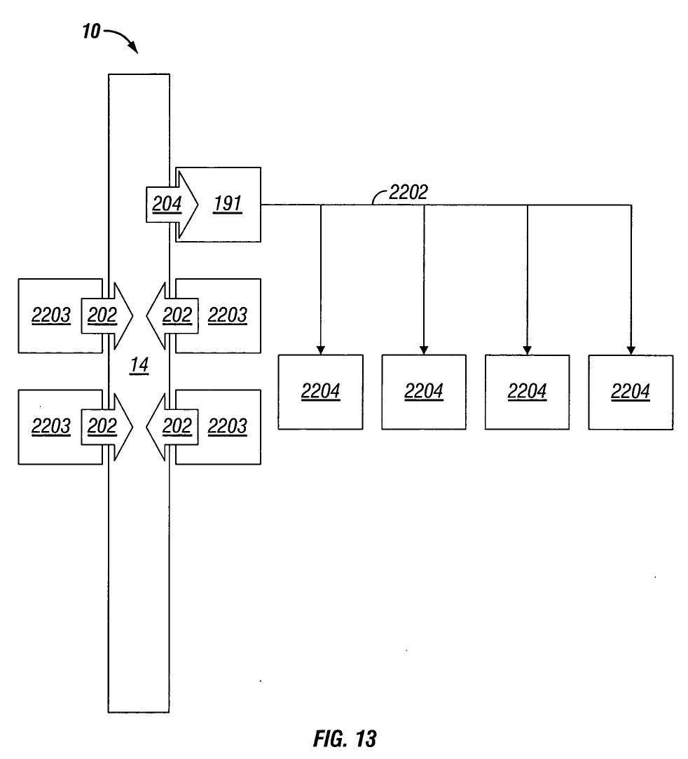

FIG. 13 shows a block diagram for sensor signals according to one embodiment of the present invention. Depicted is block 14 representing substrate 14. Arrows 202 and 204 show heat flow from ICs 2203 to substrate 14 and from substrate 14 to thermal sensor 191. ICs 2203 are preferably groups of ICs employed as DIMM instantiations, but may be other ICs. As described above, ICs 2203 may be coupled directly or indirectly to substrate 14. For example, ICs 2203 may have surfaces thermally adhered to substrate 14 or may be coupled through flexible circuitry and other ICs. ICs 2203 or thermal sensor 191 may also be disposed in cutout portions of substrate 14, such as, for example, those described above with reference to FIG. 9.

Thermal sensor 191 contains a transducer to transform a temperature signal into an electrical signal. Thus it provides a signal related to a thermal condition of the module. Heat sensor transducers are well known in the art. Many such transducers produce an analog voltage or current proportional to the measured temperature. The analog signal is preferably converted to a digital thermal signal 2202 at the output of thermal sensor 191. Other arrangements may be used. For example, signal 2202 may be an analog signal which is converted for processing elsewhere in module 10 or at circuitry outside of module 10.

The depicted thermal signal 2202 is shown connected to monitoring circuitry 2204 for four DIMM instantiations 2203. In this embodiment, four instantiations of DIMM circuitry such as, for example, the FB-DIMM circuitry or registered DIMM circuitry are mounted to flex circuitry in a single module 10. The depicted single thermal sensor provides thermal measurement for controlling and monitoring all four depicted instantiations. In other embodiments, signal 2202 may instead or additionally connect to a system monitor or other control circuitry for receiving and processing thermal monitoring signals. Such circuitry may be part of module 10 or may be located as part of the system in which module 10 is installed.

Those of skill in the art will recognize, after appreciating this specification, that more than one thermal sensor 191 may be arranged to monitor thermal status of circuitry in a module 10. For example, a thermal sensor 191 may supply a thermal measurement signal 2202 for two DIMM instantiations, one thermally mounted to each side of substrate 14. Such an embodiment may be used to advantage, for example, in systems having variations in thermal conditions from one location to another or from one DIMM instantiation to another. In a system employing FB-DIMM circuitry, DIMM instantiations closer to the system memory controller typically have greater signaling through their AMBs than do DIMM instantiations further from the system memory controller. If such DIMM instantiations are present together on a module 10, there may be control advantages in providing separate thermal measurements associated with each DIMM instantiations, or associated with circuitry along either side of substrate 14.

Although the present invention has been described in detail, it will be apparent to those skilled in the art that many embodiments taking a variety of specific forms and reflecting changes, substitutions and alterations can be made without departing from the spirit and scope of the invention. Therefore, the described embodiments illustrate but do not restrict the scope of the claims.

1. A circuit module for reducing thermal variation between constituent CSPs, the module comprising:
(a) a thermally-conductive rigid substrate having first and second lateral sides, at least one extension and an edge; and
(b) flex circuitry populated with a plurality of CSPs and exhibiting a connective facility that comprises plural contacts for use with an edge connector, the flex circuitry being wrapped about the edge of the thermally-conductive substrate.

2. The circuit module of claim 1 in which constituent CSPs of the plurality of CSPs are distributed along first and second sides of the flex circuitry.

3. The circuit module of claim 2 in which there is at least one pair of CSPs composed of a first CSP and a second CSP separated by the flex circuitry and positioned opposite each other to encourage migration of thermal energy from the first CSP to the second CSP when the first CSP is in an ON state.

4. The circuit module of claim 1 in which the plurality of CSPs are comprised of memory circuit CSPs.

5. The circuit module of claims 1 or 2 comprising an instantiation of at least one FB-DIMM circuit.

6. The circuit module of claim 1 or 2 comprising an instantiation of at least one registered DIMM circuit.

7. The circuit module of claim 1 or 2 further comprising a microprocessor.

8. The circuit module of claim 1 or 2 in which the plurality of CSPs are memory circuit CSPs.

9. The circuit module of claim 1 or 2 in which the thermally-conductive rigid substrate is comprised of aluminum.

10. The circuit module of claim 1 or 2 in which the thermally-conductive rigid substrate is comprised of copper.

11. The circuit module of claim 1 or 2 further comprising a sensor.

12. The circuit module of claim 11 in which the sensor is a thermal sensor that provides a signal related to a thermal condition of the module.

13. The circuit module of claim 11 in which the sensor provides a signal related to module capacity.

14. The circuit module of claim 1, 2 or 3 inserted into an edge connector.

15. The circuit module of claim 14 in which the edge connector is connected a computer.

16. A circuit module for reducing thermal variation between constituent CSPs, the module comprising:
(a) a thermally-conductive rigid substrate having first and second lateral sides, at least one extension and an edge; and
(b) flex circuitry comprising a first flex circuit populated with a plurality of CSPs and having plural contacts for insertion into an edge connector and a second flex circuit populated with a plurality of CSPs.

17. The circuit module of claim 16 in which each of the first and second flex circuits have first and second sides each of which sides are populated with CSPs.

18. The circuit module of claim 17 in which there is at least one pair of CSPs composed of a first CSP and a second CSP separated by the first flex circuit and positioned opposite each other to encourage conveyance of thermal energy from the one of the first and second CSPs that is in the ON state to the one of the first and second CSPs that is in a quiescent state.

19. The circuit module of claim 17 in which there is at least one pair of CSPs composed of a first CSP and a second CSP separated by the second flex circuit and positioned opposite each other to encourage conveyance of thermal energy from the one of the first and second CSPs that is in an ON state to the one of the first and second CSPs that is in a quiescent state.

20. The circuit module of claim 16 comprising an instantiation of a FB-DIMM.

21. The circuit module of claim 16 comprising an instantiation of a registered DIMM.

22. The circuit module of claim 16 further comprising a microprocessor.

23. The circuit module of claim 16 in which the thermally-conductive substrate is comprised of aluminum.

24. The circuit module of claim 16 in which the thermally-conductive substrate is comprised of copper.

25. The circuit module of claim 16 further comprising a sensor.

26. The circuit module of claim 25 in which the sensor provides a signal related a thermal condition of the module.

27. The circuit module of claim 25 in which the sensor generates a signal related to module capacity.

28. A circuit module comprising:
a thermally-conductive rigid substrate having first and second lateral sides and an edge;
flexible circuitry populated with plural CSPs and at least one sensor, the flexible circuitry being wrapped about the edge of the thermally-conductive rigid substrate.

29. The circuit module of claim 28 in which the at least one sensor is a sensor that provides a signal related to a thermal condition of the module.

30. The circuit module of claim 28 in which the at least one sensor is a sensor that provides a signal related to module capacity.

31. The circuit module of claim 28 comprising at least one FB-DIMM instantiation.

32. The circuit module of claim 28 in which at least one of the first and second lateral sides of the thermally-conductive rigid substrate has a cutout area into which is disposed a CSP.

33. The circuit module of claim 28 in which the thermally-conductive rigid substrate is comprised of aluminum.

34. A circuit module comprising:
a flex circuit having a first side and a second side, the first side exhibiting a connective facility disposed between first and second pluralities of first side memory CSPs disposed along the first side, the second side exhibiting first and second pluralities of second side memory CSPs disposed along the second side there being at least one pair of memory CSPs composed of two CSPs including a selected one of the CSPs of the first plurality of first side memory CSPs and a selected one of the CSPs of the first plurality of second side memory CSPs positioned opposite each other and separated by the flex circuit so as to encourage migration of thermal energy from the one of the two CSPs that is in an ON state to the one of the two CSPs that is in a quiescent state;
a thermally conductive substrate having first and second lateral sides and at least one extension opposite an edge of the thermally-conductive substrate, the flex circuit being disposed about the edge of the thermally-conductive substrate to dispose the connective facility more proximal to the edge of the substrate than the at least one extension.

35. The circuit module of claim 34 in which the connective facility is a plurality of edge connector contacts.

36. The circuit module of claim 34 in which the thermally-conductive substrate is comprised of aluminum.

37. The circuit module of claim 34 in which the thermally-conductive substrate is comprised of copper.
